(19) United States
(12) Patent Application Publication
(10) Pub. No.: US 2006/0068599 A1
(43) Pub. Date: Mar. 30, 2006

(54) Methods of forming a thin layer for a semiconductor device and apparatus for performing the same

(75) Inventors: Eun-Kyung Baek, Gyeonggi-do (KR); Kyu-Tae Na, Seoul (KR); Sang-Ho Rha, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/219,972

(22) Filed: Sep. 6, 2005

(30) Foreign Application Priority Data
Sep. 7, 2004 (KR) 10-2004-0071253

(51) Int. Cl. H01L 21/31

(52) U.S. Cl. 438/758

(57) ABSTRACT

The present invention can provide methods of forming a thin layer for a semiconductor device. The methods can include forming a recessed portion on an object, and forming an insulation layer on the object by reacting a water vapor, an oxygen gas including an oxygen radical and an organic silicon source gas with each other, so that the recessed portion is filled with the insulation layer. Accordingly, a flow characteristic of the insulation layer can be improved, so that a seam defect can be sufficiently decreased in the insulation layer. The present invention can further provide apparatus for forming a thin layer.

### CROSS REFERENCE TO RELATED APPLICATION

This application claims priority under 35 USC §119 to Korean Patent Application No. 10-2004-71253 filed on Sep. 7, 2004, the content of which is herein incorporated by reference in its entirety.

### FIELD OF THE INVENTION

The present invention relates to methods of forming a thin layer for a semiconductor device and an apparatus for performing the same. More particularly, the present invention relates to methods of forming a thin layer for a semiconductor device using a chemical vapor deposition (CVD) process and apparatus for performing the same.

### BACKGROUND OF THE INVENTION

Recently, as information media, such as computers, are widely used, the semiconductor industry has made great strides. In a functional aspect, it is desirable that a semiconductor device operate at a high speed and maintain large storing capacitance. Accordingly, there is a need in the semiconductor technology is developed to improve the integration degree, the reliance, and response speed of semiconductor devices.

For at least these reasons, significance has been placed on developing a method of forming a thin layer for separating semiconductor unit devices or conductive structures from each other.

Particularly, as the integration degree of a semiconductor device increases, the aspect ratio of a semiconductor device recessed portion, (e.g., a trench, a contact hole, a via hole, a gap and the like) between conductive patterns may also increase. Thus, various techniques have been suggested for improving a gap-fill characteristic of a thin layer covering the recessed portion.

Among the techniques for improving the gap-fill characteristic of a thin layer, a method of forming a silicon oxide (SiO₂) layer using a tetra ethoxy silane (Si(OC₂H₅)₄) (TEOS) and ozone (O₃) by a CVD process is widely used during a semiconductor device manufacturing process.

In such a process, TEOS and ozone may be supplied to a processing chamber at a temperature in a range of about 400° C. to about 550° C., and may be chemically reacted with each other in the processing chamber at a pressure in a range of about 300 Torr to about 600 Torr. The above CVD process is often called “sub-atmospheric CVD” (SACVD) because the SiO₂ layer may be formed under an atmospheric pressure (about 760 Torr).

The SiO₂ layer may be formed based on the following chemical equation (1) from the TEOS gas and the ozone gas.
Si(OC₂H₅)₄+6O₃→SiO₂+10H₂O+8CO+O₂ (1)
As indicated in the above chemical equation (1), the ozone gas is dissolved into oxygen (O₂) gas and oxygen radical (O*), and the Si(OC₂H₅)₄ gas is reacted with the oxygen radical (O*) in the processing chamber. Accordingly, a silicon oxide (SiO₂) layer may be coated on a surface of the substrate, and byproducts of the above chemical reaction may be exhausted from the chamber as a water vapor (H₂O), a carbon dioxide (CO₂) gas and an oxygen (O₂) gas.

However, there is a problem that the above silicon oxide (SiO₂) layer may include a seam defect, and the seam defect can be problematic in a subsequent process. That is, an etchant in a subsequent wet etching process may enlarge the seam defect on the SiO₂ layer, and a conductive material may be filled into the enlarged seam defect, thereby potentially generating a short circuit between conductive structures in a semiconductor device, and a reliance reduction of a device.

In addition; the silicon oxide (SiO₂) layer may have a limit in a gap-fill characteristic since an aspect ratio thereof may be very high due, at least in part, to a high integration degree.

As a solution for the above problem of the poor gap-fill characteristic in the silicon oxide (SiO₂) layer, there has been suggested that a water vapor may be utilized as a source gas for the CVD process. For example, according to the article entitled “A ROOM TEMPERATURE CVD TECHNOLOGY FOR INTERLAYER IN DEEP-SUBMICRON MULTILEVEL INTERCONNECTION”, IEDM, 1991, p. 289-292, the disclosure of which is incorporated herein by reference in its entirety, an insulation interlayer having good step coverage is formed by a CVD process using a fluorotriethoxy silane (FSi(OC₂H₅)₄) and a water vapor as a source gas at a temperature of about 25° C. The insulation interlayer discussed in the above IEDM article is confirmed to have sufficiently good step coverage.

Furthermore, according to the article entitled “H₂O-TEOS PLASMA-CVD REALIZING DIELECTRIC HAVING A SMOOTH SURFACE”, VMIC Conference, 1991, p. 435-437, the disclosure of which is incorporated herein by reference in its entirety, a dielectric layer having a good gap-fill characteristic is formed through a plasma enhanced CVD process using TEOS and a water vapor as a source gas at a temperature of about 37° C. In the above PECVD process, the source gas is activated in a plasma atmosphere. The dielectric layer discussed in the above VMIC conference article is confirmed to have a sufficiently good gap-fill characteristic.

In addition, U.S. Pat. No. 5,868,849 (issued to Nakao et al.) the disclosure of which is incorporated herein by reference in its entirety, proposes that a thin layer is formed via a CVD process using TEOS and a water vapor as a source gas. In the above CVD process, the water vapor is selectively heated by using microwaves. The thin layer discussed in the above U.S patent is confirmed to have sufficiently good step coverage.

However, it is believed that the above suggestions may not provide a solution to the problems in that the CVD process may be difficult to control due to a low processing temperature and an additional unit may be useful for generating the plasma and microwaves.

### SUMMARY OF THE INVENTION

The present invention provides methods of forming a thin layer. In particular, the thin layer possesses a good gap-fill characteristic to sufficiently fulfill the high integration degree of a semiconductor device.

The present invention also provides an apparatus for performing the above methods.

According to some embodiments of the present invention, there is provided a method of forming a thin layer for a semiconductor device. A recessed portion is formed on an object in a processing chamber. A water vapor is exemplarily produced by a chemical reaction of a hydrogen gas and an oxygen gas. The water vapor, an oxygen gas including an oxygen radical and an organic silicon source gas are supplied into the processing chamber, and reacted with each other on a surface of the object, thereby forming an insulation layer on the object. As a result, the recessed portion is filled with the insulation layer.

Some embodiments of the present invention provide further methods of forming a thin layer for a semiconductor device. A recessed portion is formed on an object in a processing chamber. A first insulation layer is formed on the object and inner surfaces of the recessed portion by reacting an organic silicon source gas with ozone gas, so that a size of the recessed portion is reduced. Namely, the recessed portion is changed into a reduced recess. A water vapor is produced by a chemical reaction of a hydrogen gas and an oxygen gas. A second insulation layer is formed on the first insulation layer by reacting the water vapor, an oxygen gas including an oxygen radical and an organic silicon source gas with each other, so that the reduced recess is filled with the second insulation layer.

Further embodiments of the present invention provide apparatus for forming a thin layer for a semiconductor device. The apparatus include a processing chamber into which an object including a recessed portion is loaded, a first gas supplier for supplying a water vapor into the processing chamber, a second gas supplier for supplying an oxygen gas including an oxygen radical into the processing chamber, and a third gas supplier for supplying an organic silicon source gas into the processing chamber. An insulation layer is formed on the object by a chemical reaction between the water vapor, the oxygen gas including the oxygen radical and the organic silicon source gas, so that the recessed portion is filled with the insulation layer in the processing chamber. According to some embodiments, the apparatus may further include a fourth gas supplier for additionally supplying the oxygen gas including the oxygen radical into the processing chamber.

In some embodiments of the present invention, the recessed portion includes a trench on a semiconductor substrate, or the object includes one of a thin layer and a conductive structure on a semiconductor substrate, and the recessed portion includes one of a via-hole or a contact hole penetrating the thin layer and a gap between the conductive structures.

According to some embodiments of the present invention, a flow characteristic and a gap-fill characteristic of the insulation layer are sufficiently improved, so that a seam defect is remarkably decreased when the recessed portion is filled with the insulation layer.

### BRIEF DESCRIPTION OF THE DRAWINGS

FIGS. 1 to 3 are cross sectional views illustrating processing steps for methods of forming a thin layer for a semiconductor device according to some embodiments of the present invention;

FIGS. 4 and 5 are cross sectional views illustrating processing steps for methods of forming a thin layer for a semiconductor device according to some embodiments of the present invention;

FIGS. 6 and 7 are cross sectional views illustrating processing steps for methods of forming a thin layer for a semiconductor device according to some embodiments of the present invention;

FIGS. 8 and 9 are cross sectional views illustrating processing steps for methods of forming a thin layer for a semiconductor device according to some embodiments of the present invention;

FIG. 10 is a structural view schematically illustrating an apparatus for forming a thin layer for a semiconductor device according to embodiments of the present invention;

FIG. 11 is a flow chart illustrating processing steps for a method of forming a thin layer for a semiconductor device according to some embodiments of the present invention;

FIG. 12 is a structural view schematically illustrating an apparatus for forming a thin layer for a semiconductor device according to some embodiments of the present embodiment;

FIG. 13 is a structural view schematically illustrating an apparatus for forming a thin layer for a semiconductor device according to some embodiments of the present embodiment;

FIG. 14 is a vertical picture of a conventional insulation layer filling a recessed portion of a substrate vertically taken by a scanning electron microscope (SEM);

FIG. 15 is a horizontal picture of a conventional insulation layer filling a recessed portion of a substrate horizontally taken by a SEM;

FIG. 16 is a vertical picture of an insulation layer filling a recessed portion of a substrate according to some embodiments of the present invention taken vertically by a SEM;

FIG. 17 is a horizontal picture of a conventional insulation layer filling a recessed portion of a substrate according to some embodiments of the present invention horizontally taken by a SEM; and

FIG. 18 is a graph illustrating a stress hysteresis of each of the silicon oxide (SiO2) layer on the first substrate and the insulation layer on the second substrate.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “up”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Moreover, it will be understood that steps comprising the methods provided herein can be performed independently or at least two steps can be combined. Additionally, steps comprising the methods provided herein, when performed independently or combined, can be performed at the same temperature and/or atmospheric pressure or at different temperatures and/or atmospheric pressures without departing from the teachings of the present invention.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments of the present invention provide methods of forming a thin layer for a semiconductor device. In particular, FIGS. 1 to 3 are cross sectional views illustrating processing steps for a method of forming a thin layer for a semiconductor device according to some embodiments of the present invention. In some embodiments, the thin layer is formed on a semiconductor substrate, and a recessed portion is illustrated as a trench formed on the substrate. However, an object on which the thin layer is formed and the recessed portion on the object should not be limited to this exemplary semiconductor substrate and the trench but various equivalents known by one skilled in the art within the spirit and scope of the present invention may be utilized in place of the semiconductor substrate and trench.

Referring to FIG. 1, a buffer oxide layer 12 and a silicon nitride layer 14 for a hard mask are sequentially coated on an object such as the semiconductor substrate 10.

The buffer oxide layer 12 may be formed by a rapid thermal oxidation (RTO) process, a furnace thermal oxidation process or a plasma oxidation process. In some embodiments, the RTO process is performed at a pressure of a few Torr and at a substrate temperature in a range of about 800° C. to about 950° C. for a period of time in a range of about 10 seconds to about 30 seconds. As a result, a surface of the substrate 10 is oxidized to thereby form the buffer oxide layer 12 on the substrate 10. The substrate 10 may be heated such as by an infrared light generated from a tungsten halogen lamp or an arc lamp. Although the above embodiments discuss the tungsten halogen lamp and the arc lamp, the substrate 10 could also be created by microwave or any other heating technique known to one of the ordinary skill in the art.

When the silicon nitride 14 layer makes direct contact with the substrate 10, an internal stress may be increased at a boundary surface of the silicon nitride 14 layer and the substrate 10, so that the buffer oxide layer 12, interposed between the silicon nitride 14 layer and the substrate 10, may sufficiently reduces the internal stress.

The silicon nitride layer 14 may be formed on the buffer oxide layer 12 by a low pressure CVD (LPCVD) process using a silicon source gas and a nitrogen source gas. Examples of the silicon source gas include a silane gas (SiH₄), a SiH₂Cl₂ (dichlorosilane) gas, a silicon tetrachlorine (SiCl₄), etc. These can be used alone or in combinations thereof. Examples of the nitrogen source gas include a nitrogen (N₂) gas, an ammonia (NH₃) gas, nitrous oxide (N₂O) gas, etc. These can be used alone or in combinations thereof.

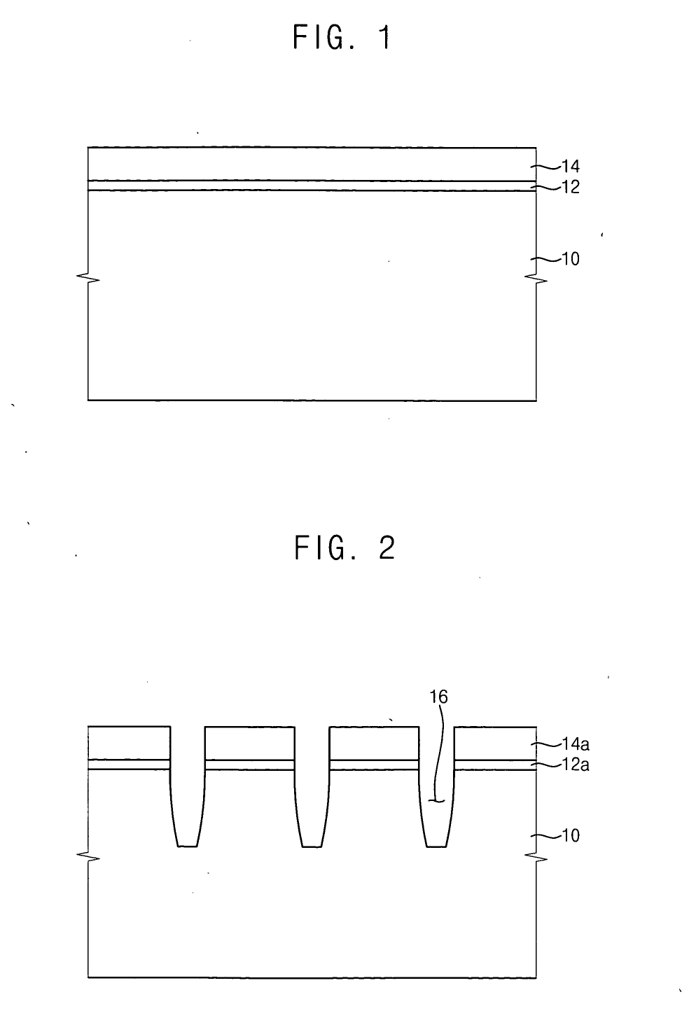

Referring to FIG. 2, a photolithography process is performed against the silicon nitride layer 14, thereby forming a hard mask pattern 14a. A field region of the substrate 10 is selectively exposed through the hard mask pattern 14a. Then, the buffer oxide layer 12 is selectively dry etched using the hard mask pattern 14a as an etching mask, thereby forming a buffer oxide pattern 12a. The substrate 10 exposed through the hard mask pattern 14a is also dry etched using the hard mask pattern 14a as an etching mask, thereby forming a recessed portion 16 on the substrate 10.

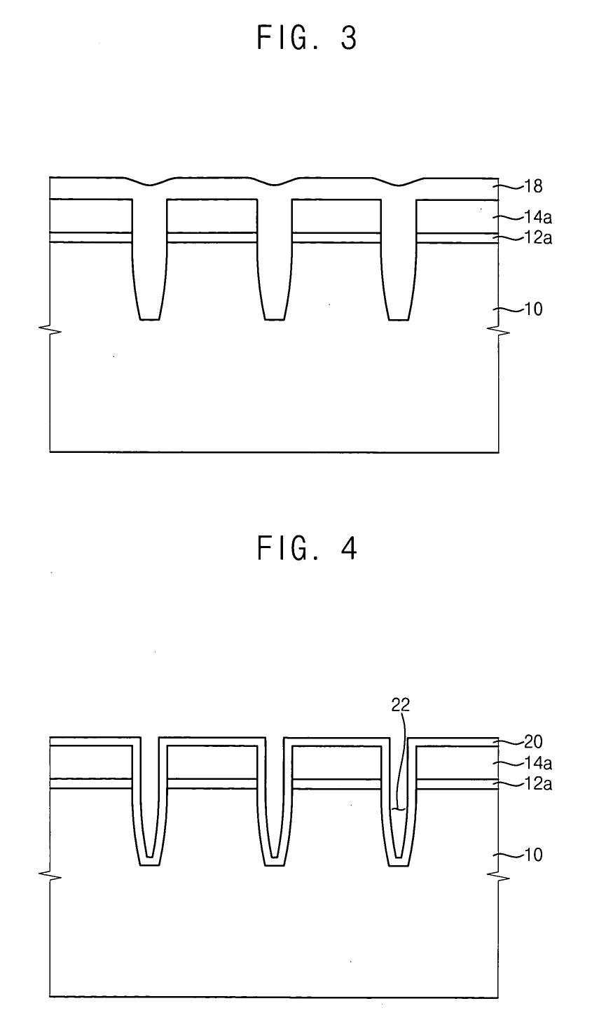

Referring to FIG. 3, an insulation layer 18 is coated on the hard mask pattern 14a to a sufficient thickness to fill the recessed portion 16 of the substrate 10 and gaps between the hard mask pattern 14a and buffer oxide pattern 12a by a sub-atmospheric CVD (SACVD) process in which the CVD process is performed at a pressure lower than an atmospheric pressure.

Particularly, a water vapor, an oxygen (O₂) gas including an oxygen radical (O*) and an organic silicon source gas are supplied into a processing chamber for the SACVD process. In some embodiments, the water vapor is generated from an additional water vapor generator. A hydrogen source gas and an oxygen source gas are supplied to the water vapor generator, and the hydrogen and oxygen atoms are reacted with each other, thereby producing the water vapor. The water vapor is then supplied to the processing chamber.

The water vapor, the oxygen gas and the organic silicon source gas are chemically reacted with each other in the processing chamber at a lower pressure than an atmospheric pressure, thereby forming the insulation layer 18 (that fills the recess 16) on the hard mask layer 14a.

A process reaction in the processing chamber is based on a hydrolysis reaction, so that the source gas may include an Si(OR)4 (wherein, OR denotes an alkoxy group) structure therein.

Examples of the organic silicon source gas including the Si(OR)4 structure may include a tetra ethoxy silane (Si(OC₂H₅)₄, TEOS) gas, a tetra methoxy silane (Si(OCH₃)₄) gas, a tetra isopropoxy silane (Si(i-OC₃H₇)₄) gas, a tetra tertiary butoxy silane (Si(t-OC₄H₉)₄) gas, and the like. These can be used alone or in combinations thereof, the selection of which will be within the knowledge of one skilled in the art. In one present embodiment, the TEOS gas is used as the organic silicon source gas for the SACVD process.

The water vapor is supplied to the processing chamber at a flow rate ratio of about 40 to about 75 with respect to the organic silicon gas, and the oxygen gas is supplied to the processing chamber at a flow rate ratio of about 75 to about 170 with respect to the organic silicon gas. For example, when the organic silicon gas is supplied to the processing chamber at a flow rate of about 100 standard cubic centimeters per minute (sccm), the water vapor is supplied at a flow rate in a range of about 4000 sccm to about 7500 sccm, and the oxygen gas is supplied at a flow rate in a range of about 7500 sccm to about 17000 sccm.

In some embodiments, the water vapor is supplied to the processing chamber at a flow rate of about 4000 sccm, the oxygen gas is supplied at a flow rate of about 7500 sccm, and TEOS gas is supplied at a flow rate of about 100 sccm as the organic silicon source gas. That is, the ratio of the flow rate of the source gases is about 40:75:1 in the present embodiment.

In the above SACVD exemplary process, an internal pressure of the processing chamber is maintained to be lower than an atmospheric pressure, and the temperature of the substrate 10 is in a range of about 25° C. to 500° C. In some embodiments, the internal pressure of the processing chamber is set to be about 600 Torr, and the temperature of the substrate 10 is set to be about 540° C.

In some embodiments, the oxygen gas including oxygen radical (O*) is generated from an ozone generator and a remote plasma system, and is then supplied to the processing chamber.

As provided in some embodiments, the insulation layer 18 is formed in the processing chamber through the chemical reaction expressed as the following chemical equation (2).
Si(OC₂H₅)₄+4H₂O Si(OH)₄+4C₂H₅OH (2)

At first, TEOS is hydrolyzed into silicon hydroxide (Si(OH)₄) and ethyl alcohol by an oxygen radical catalyst followed by deposition of silicon hydroxide on the hard mask pattern 14a including the recessed portion 16 with the water vapor. Thereafter, the deposited silicon hydroxide is converted (or generated or produced) into silicon oxide such as by a poly-condensation reaction due to heat, thereby forming an insulation layer 18 on the hard mask pattern 14a.

Accordingly, a flow characteristic of the insulation layer 18 may be sufficiently improved, so that the seam defect may be difficult to generate in the above-described insulation layer 18, thereby improving the device reliance of the semiconductor device.

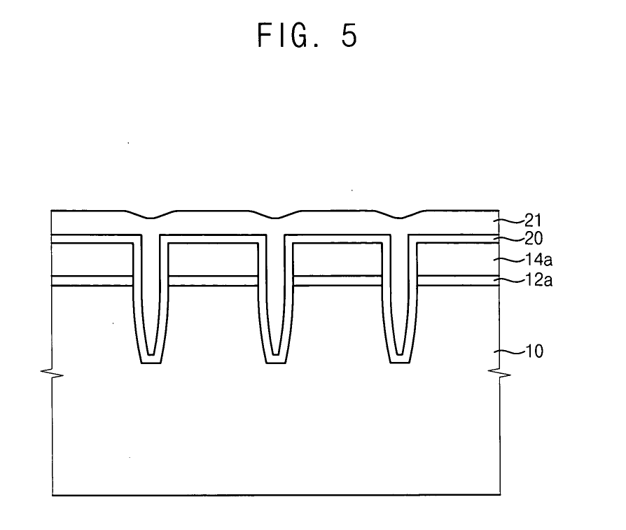

FIGS. 4 and 5 are cross sectional views illustrating processing steps for methods of forming a thin layer for a semiconductor device according to some embodiments of the present invention. The processing steps are similar to those described above except with respect to the method of forming the insulation layer. Accordingly, any further detailed description on forming the recessed portion on the object will be omitted, and the same reference numbers will be used to refer to the same or like parts as those used above.

Referring to FIG. 4, a recessed portion as shown in FIG. 2 as a reference number 16 is formed on an object or a substrate 10 including a buffer oxide pattern 12a and a hard mask pattern 14a in the same way as described above, and a first insulation layer 20 is formed along a profile of the substrate 10 including the recessed portion 16. That is, the first insulation layer 20 is formed on top and side surfaces of the hard mask pattern 14a, on a side surface of the buffer oxide pattern 12a and on inner surfaces of the recessed portion 16. A silicon oxide (SiO₂). layer is coated along the profile of the substrate 10 by the SACVD process, thereby forming the first insulation layer 20. Particularly, an ozone gas and an organic silicon gas may be reacted with each other on a surface of the substrate 10 including the recessed portion 16, thereby forming the first insulation layer 20. Because the first insulation layer 20 is coated on an inner surface of the recessed portion 16, a volume size of the recessed portion 16 is reduced. Hereinafter, the recessed portion 16 having the reduced size is referred to as a reduced recess 22. In some embodiments, a TEOS gas is utilized as the organic silicon source gas, and the first insulation layer 20 includes a silicon oxide layer.

Referring to FIG. 5, a second insulation layer 21 is formed on the first insulation layer 20 to a sufficient thickness to fill the reduced recess 22 with the insulation layer 18 formed by the same process described above using the SACVD process.

Particularly, a water vapor, an oxygen (O₂) gas including an oxygen radical (O*) and an organic silicon source gas are supplied into a processing chamber for the SACVD process. In some embodiments, the water vapor is generated from an additional water vapor generator. A hydrogen source gas and an oxygen source gas are supplied to the water vapor generator, and the hydrogen and oxygen atoms are reacted with each other, thereby producing the water vapor.

The water vapor is then supplied to the processing chamber. The water vapor, the oxygen gas and the organic silicon source gas are chemically reacted with each other in the processing chamber at a pressure lower than an atmospheric pressure, thereby forming the second insulation layer 21 (that fills the second recess 22) on the second insulation layer 20. In some embodiments, the second insulation layer 21 also includes silicon oxide.

Examples of the organic silicon source gas include a tetra ethoxy silane Si(OC₂H₅)₄, TEOS) gas, a tetra methoxy silane (Si(OCH₃)₄) gas, a tetra isopropoxy silane (Si(i-OC₃H₇)₄) gas, a tetra tertiary butoxy silane (Si(t-OC₄H₉)₄) gas, etc. These can be used alone or in combinations thereof. In some embodiments, the TEOS gas is used as the organic silicon source gas for the SACVD process.

The water vapor is supplied to the processing chamber at a flow rate ratio of about 40 to about 75 with respect to a unit flow rate of the organic silicon source gas, and the oxygen gas are supplied to the processing chamber at a flow rate ratio of about 75 to about 170 with respect to a unit flow rate of the organic silicon source gas. For example, when the organic silicon gas is supplied to the processing chamber at a flow rate of about 100 sccm, the water vapor is supplied at a flow rate in a range of about 4000 sccm to about 7500 sccm, and the oxygen gas is supplied at a flow rate in a range of about 7500 sccm to about 17000 sccm.

In some embodiments, the water vapor is supplied to the processing chamber at a flow rate of about 4000 sccm, the oxygen gas is supplied at a flow rate of about 7500 sccm, and TEOS gas is supplied at a flow rate of about 100 sccm as the organic silicon source gas. That is, the ratio of the flow rate of the source gases is about 40:75:1.

In the above SACVD process, an internal pressure of the processing chamber is maintained to be lower than an atmospheric pressure, and the temperature of the substrate 10 is in a range of about 25° C. to about 500° C. In some embodiments, the internal pressure of the processing chamber is set to be about 600 Torr, and the temperature of the substrate 10 is set to be about 540° C.

In some embodiments, the oxygen gas including the oxygen radical is generated from an ozone generator and a remote plasma system, and subsequently supplied to the processing chamber for the SACVD process.

As provided in some embodiments of the present invention, the second insulation layer 21 is formed in the processing chamber through the chemical reaction expressed as the following chemical equation (3).
Si(OC₂H₅)₄+4H₂O→Si(OH)₄+4C₂H₅OH (3)

At first, TEOS is hydrolyzed into silicon hydroxide and ethyl alcohol by an oxygen radical catalyst, and then the silicon hydroxide is deposited on the first insulation layer 20 including the reduced recess 22 with the water vapor. Thereafter, the deposited silicon hydroxide is converted into silicon oxide by a poly-condensation reaction due to heat, thereby forming the second insulation layer 21 on the first insulation layer 20.

Accordingly, a flow characteristic of the second insulation layer 21 may be sufficiently improved, so that the seam defect may be difficult to generate in the above-described second insulation layer 21, thereby improving the device reliance of the semiconductor device.

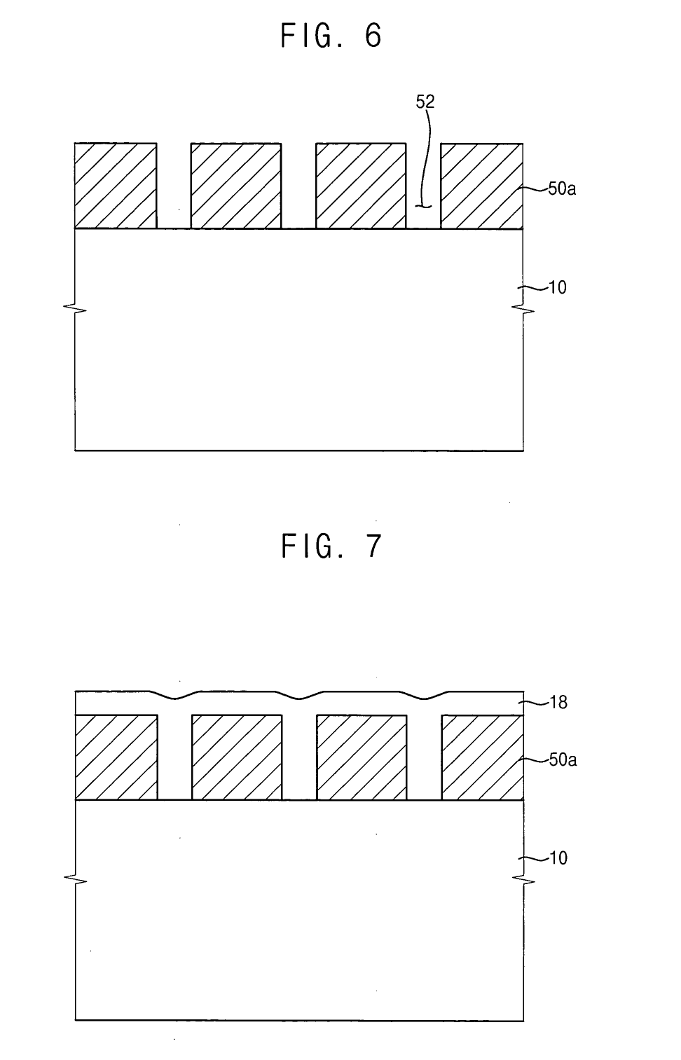

FIGS. 6 and 7 are cross sectional views illustrating processing steps for methods of forming a thin layer for a semiconductor device according to some embodiments of the present invention. The processing steps are similar to those described above except with respect to the method of forming a recessed portion on an object. Thus, any further detailed description on forming the insulation layer will be omitted. In some embodiments, the object may be a thin layer or a conductive structure on a semiconductor substrate, and the recessed portion may be a via-hole, a contact hole or a gap between the conductive structures.

Accordingly, the object and a recessed portion on the object will be further described and the insulation layer on the object is described to a lesser extent in view of the foregoing. For this reason, the same reference numbers will be used to refer to the same or like parts as those used above.

Referring to FIG. 6, an object (not shown) is formed on a semiconductor substrate 10, and a photoresist pattern (not shown) is formed on the object by a photo process. Then, the object is partially etched off using the photoresist pattern as an etching mask, so that an object pattern 50a is formed on the substrate 10. As a result, a top surface of the substrate 10 is partially exposed through a gap 52 between the object patterns 50a.

Referring to FIG. 7, an insulation layer 18 is coated on the object pattern 50a to a sufficient thickness to fill the gap 52 by the SACVD process in which the CVD process is performed at a pressure lower than an atmospheric pressure.

Particularly, a water vapor, an oxygen gas including an oxygen radical and an organic silicon source gas are supplied into a processing chamber for the SACVD process. In some embodiments, the water vapor is generated from an additional water vapor generator. A hydrogen source gas and an oxygen source gas are supplied to the water vapor generator, and the hydrogen and oxygen atoms are reacted with each other, thereby producing the water vapor. The water vapor is then supplied to the processing chamber. The water vapor, the oxygen gas and the organic silicon source gas are chemically reacted with each other in the processing chamber at a lower pressure than an atmospheric pressure, thereby forming the insulation layer 18 on the object pattern 50a.

Accordingly, a flow characteristic of the insulation layer 18 may be sufficiently improved, so that the seam defect may be difficult to generate in the above insulation layer 18 for filling the gap 52, thereby improving the device reliance of the semiconductor device.

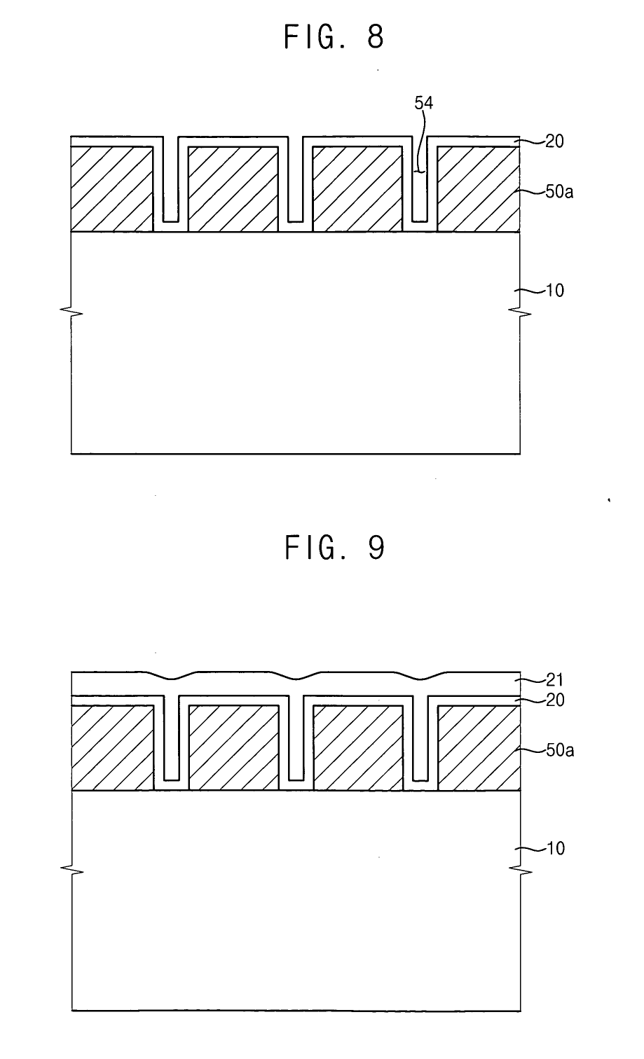

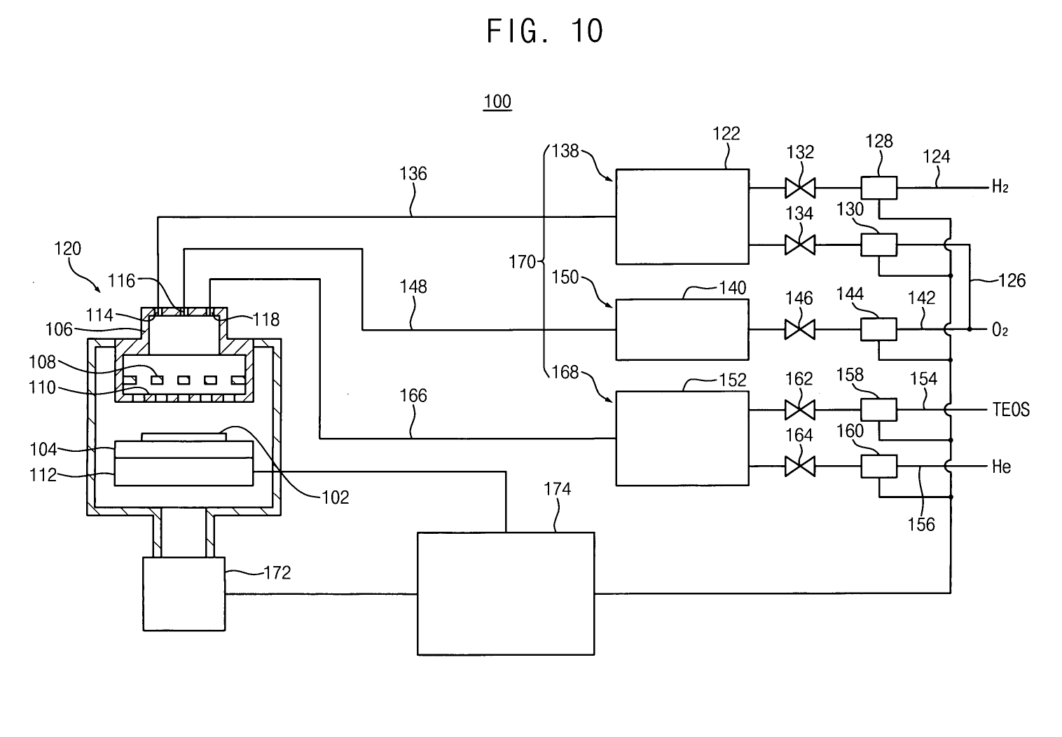

FIGS. 8 and 9 are cross sectional views illustrating processing steps for methods of forming a thin layer for a semiconductor device according to some embodiments of the present invention. The processing steps are similar to those described above except with respect to the method of forming a recessed portion on an object. Thus, any further detailed description on forming the insulation layer will be omitted. In some embodiments, the object may be a thin layer or a conductive structure on a semiconductor substrate, and the recessed portion may be a via-hole, a contact hole or a gap between the conductive structures as described above.

Accordingly, the detailed description below is focused on the object and a recessed portion on the object, and the insulation layer on the object is described to a lesser extent in view of the foregiong. For this reason, the same reference numbers will be used to refer to the same or like parts as those used above.

Referring to FIG. 8, an object (not shown) is formed on a semiconductor substrate 10, and then an object pattern 50a is formed on the substrate 10 in the same process as described above. As a result, a top surface of the substrate 10 is partially exposed through a gap 52 between the object patterns 50a. Then, a first insulation layer 20 is formed along a profile of the object pattern 50a including the gap 52. That is, the first insulation layer 20 is formed on top and side surfaces of the object pattern 50a, and on the top surface of the substrate 10 in the gap 52. Because the first insulation layer 20 is coated on an inner surface of the gap 52, a volume size of the gap 52 may be reduced. Hereinafter, the gap 52 having a reduced size is referred to as a reduced gap 54. In some embodiments, a TEOS gas is utilized as the organic silicon source gas, and the first insulation layer 20 is a silicon oxide layer.

Referring to FIG. 9, a second insulation layer 21 is formed on the first insulation layer 20 to a sufficient thickness to fill the reduced gap 54 with the insulation layer 18 by the same process as described above using the SACVD process.

Particularly, a water vapor, an oxygen gas including an oxygen radical and an organic silicon source gas are supplied into a processing chamber for the SACVD process. In some embodiments, the water vapor is generated from an additional water vapor generator. A hydrogen source gas and an oxygen source gas are supplied to the water vapor generator, and the hydrogen and oxygen atoms are reacted with each other, thereby producing the water vapor. The water vapor is then supplied to the processing chamber. The water vapor, the oxygen gas and the organic silicon source gas are chemically reacted with each other in the processing chamber at a lower pressure than an atmospheric pressure, thereby forming the second insulation layer 21 on the first insulation layer 20 to a sufficient thickness to fill the reduced gap 54. In some embodiments, the second insulation layer 21 may also include silicon oxide.

Accordingly, a flow characteristic of the second insulation layer 21 may be sufficiently improved, so that the seam defect may be difficult to generate in the above second insulation layer 21 for filling the reduced gap 54, thereby improving the device reliance of the semiconductor device.

Hereinafter, an apparatus for performing the method of forming a thin layer for a semiconductor device will be described in detail with reference to accompanying drawings. In particular, FIG. 10 is a structural view schematically illustrating an apparatus for forming a thin layer for a semiconductor device according to some embodiments of the present invention. Referring to FIG. 10, an apparatus 100 for forming a thin layer for a semiconductor device according to some embodiments of the present invention includes a processing chamber 120, a gas supplier 170, a pressure regulator 172 and a central controller 174.

The processing chamber 120 exemplarily includes a supporting plate 104 on which an object 102 (e.g., substrate) is positioned, a manifold 106, a gas dispersion plate 108, a showerhead 110 and a heater 112.

In some embodiments, the manifold 106 includes a first inlet 114 through which the water vapor is supplied into the processing chamber 120, a second inlet 116 through which the oxygen gas including the oxygen radical is supplied into the processing chamber 120, and a third inlet 118 through which the organic silicon gas is supplied into the processing chamber 120.

A series of the gas dispersion plates 108 is positioned under the manifold 106, so that the above gases supplied through the manifold 106 are uniformly dispersed onto an effective area of the processing chamber 120.

The showerhead 110 is positioned under gas dispersion plate 108, so that the above dispersion gases through the gas dispersion plate 108 are more uniformly and minutely supplied to a top surface of an object 102.

The heater 112 is positioned at a bottom portion of the supporting plate 104 in a body with the supporting plate 104, so that the object 102 is heated to a predetermined temperature by the heater 112. The heater 112 includes a heating element such as an electric heat coil (not shown). In some embodiments, the heater 112 heated the object 102 to a temperature in a range of about 25° C. to about 550° C. when a thin layer is formed on the object 102.

The gas supplier 170 is connected to the manifold 106 of the processing chamber 120, and supplies the above gases into the processing chamber 120. Particularly, the gas supplier 170 includes first, second and third gas suppliers 138, 150 and 168.

The first gas supplier 138 generates the water vapor using hydrogen gas and oxygen gas, and supplies the water vapor to the processing chamber 120. In some embodiments, the first gas supplier 138 includes a water vapor generator 122, first and second mass flow controllers 128 and 130 and first and second valves 132 and 134.

The water vapor generator 122 is simultaneously connected to a hydrogen pipe line 124, a first oxygen pipe line 126 and a vapor pipe line 136. The hydrogen gas and oxygen gas are provided into the water vapor generator 122 through the hydrogen pipe line 124 and the first oxygen pipe line 126, and are converted into the water vapor in the water vapor generator 122. Then, the water vapor is supplied into the processing chamber 120 through the vapor pipe line 136.

The first mass flow controller 128 is mounted on the hydrogen pipe line 124, thereby controlling a mass flow of the hydrogen gas, and the second mass flow controller 130 is mounted on the first oxygen pipe line 126, thereby controlling a mass flow of the oxygen gas.

The first valve 132 is installed on the hydrogen pipe line 124 between the water vapor generator 122 and the first mass flow controller 128, and the second valve 134 is installed on the first oxygen pipe line 126 between the water vapor generator 122 and the second mass flow controller 130.

A liquid injection system has been utilized for supplying a water vapor into a processing chamber in a conventional method of forming a thin layer for a semiconductor device, and the liquid injection system may be difficult to vaporize a large amount of liquid water, so that a large quantity of water vapor may not be supplied to the processing chamber.

However, a sufficient quantity of the hydrogen and oxygen gases is supplied to the water vapor generator 122 by the first and second mass flow controllers 128 and 130 and the first and second valves 132 and 134, and thus a sufficient and accurate quantity of water vapor may be supplied to the processing chamber 120. In some embodiments, the water vapor is supplied at a flow rate of about 50 liters/min.

The second gas supplier 150 generates the oxygen gas including the oxygen radical, and supplies the oxygen gas to the processing chamber 120 through an ozone pipe line 148. In some embodiments, the second gas supplier 150 includes an ozone generator 140, a third mass flow controller 144 and a third valve 146.

The ozone generator 140 is simultaneously connected to a second oxygen pipe line 142, and the oxygen gas is provided into the ozone generator 140 through the second oxygen pipe line 142. The oxygen gases are activated in the ozone generator 140 and a portion of the oxygen gases is converted into ozone gases, thereby forming a mixture of the oxygen gas and the ozone gas. In some embodiments, a volume ratio of the ozone gas with respect to the mixture is in a range of about 5% to about 20%.

The third mass flow controller 144 is mounted on the second oxygen pipe line 142, thereby controlling a mass flow of the oxygen gas into the ozone generator 140.

The third valve 146 is installed on the second oxygen pipe line 142 between the ozone generator 140 and the third mass flow controller 144.

As shown in FIG. 10, the first and second oxygen pipe lines 126 and 142 are diverted from the same oxygen source (not shown), so the oxygen gas is supplied to the water vapor generator 122 and the ozone generator 140 from the same oxygen source in some embodiments.

The third gas supplier 168 supplies the organic silicon source gas into the processing chamber 120. Examples of the organic silicon source gas include a tetra ethoxy silane gas, a tetra methoxy silane gas, a tetra isopropoxy silane gas, a tetra tertiary butoxy silane gas, etc. These can be used alone or in combinations thereof. In the present embodiment, the tetra ethoxy silane (TEOS) gas is used as the organic silicon source gas.

In some embodiments, the third gas supplier 168 evaporates a liquid TEOS and supplies a vaporized TEOS into the processing chamber 120, and includes an evaporator 152, fourth and fifth mass flow controllers 158 and 160 and fourth and fifth valves 162 and 164.

The evaporator 152 is simultaneously connected to a first TEOS pipe line 154, a helium pipe line 156 and a second TEOS pipe line 166. A liquefied TEOS is provided into the evaporator 152 through the first TEOS pipe line 154 and is evaporated into a vaporized TEOS in the evaporator 152. Then, the vaporized TEOS is supplied into the processing chamber 120 through the second TEOS pipe line 166.

The fourth mass flow controller 158 is mounted on the first TEOS pipe line 154, thereby controlling a mass flow of the liquefied TEOS, and the fourth valve 162 is installed on the first TEOS pipe line 154 between the evaporator 152 and the fourth mass flow controller 158.

A helium gas is supplied to the evaporator 152 simultaneously with the liquefied TEOS as a carrier gas through the helium pipe line 156, so that the evaporation of the liquefied TEOS can be accelerated by the helium. The fifth mass flow controller 160 is mounted on the helium pipe line 156, thereby controlling a mass flow of the helium gas, and the fifth valve 164 is installed on the helium pipe line 156 between the evaporator 152 and the fifth mass flow controller 160.

The pressure regulator 172 is connected to the processing chamber 120 and includes a vacuum pump (not shown) for regulating an internal pressure of the processing chamber in a range between about 100 Torr and about 760 Torr. In addition, the pressure regulator 172 also exhausts byproducts of the CVD process from the processing chamber 120.

The central controller 174 includes a gas control unit (not shown) for transferring a control signal to the first, second, third, fourth and fifth mass flow controllers 128, 130, 144, 158 and 160, a temperature control unit (not shown) for controlling a temperature of an object 102 positioned on the supporting plate 104, and a pressure control unit (not shown) for controlling the internal pressure of the processing chamber 120.

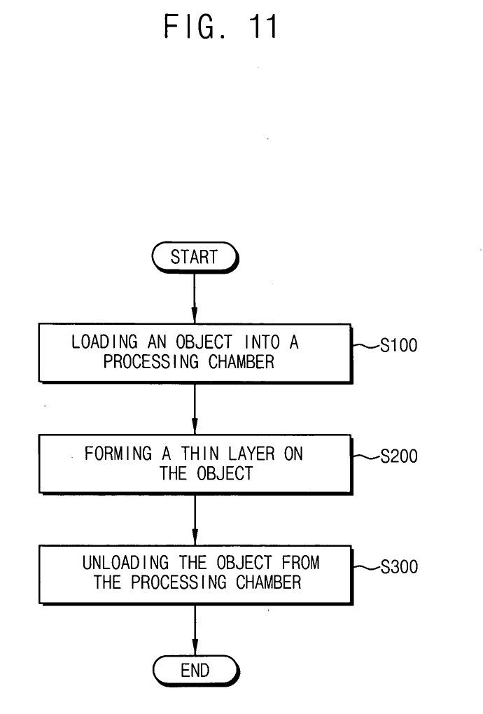

Hereinafter, methods of forming a thin layer for a semiconductor device in the above apparatus will be disclosed with reference to FIGS. 10 and 11. In particular, FIG. 11 is a flow chart illustrating processing steps for methods of forming a thin layer for a semiconductor device according to some embodiments of the present invention.

Referring to FIGS. 10 and 11, the object 102 is loaded on the supporting plate 104 of the processing chamber 120 by using a transfer member (not shown) (step S100).

A thin layer is formed on the object 102 using the above apparatus 100 shown in FIG. 10. Particularly, the object 102 is heated to a temperature of about 540° C. by the heater 112 including an electric heating coil (not shown). Then, the water vapor is supplied into the processing chamber 120 from the water vapor generator 122 at a flow rate of about 4000 sccm through the vapor pipe line 136, and the oxygen gas including the oxygen radical is also supplied into the processing chamber 120 through the ozone pipe line 148 at a flow rate of about 7500 sccm. Further, the vaporized TEOS is supplied into the processing chamber 120 from the evaporator 152 through the second TEOS pipe line 166 at a flow rate of about 100 sccm. The pressure regulator 172 controls the internal pressure of processing chamber 120 to be about 600 Torr.

The TEOS and the water vapor are chemically reacted with each other using the ozone as a catalyst under the above processing conditions of the processing chamber 120. As a result, the TEOS is hydrolyzed into silicon hydroxide and ethyl alcohol by a catalyst of the oxygen radical, and then the silicon hydroxide (Si(OH4) is deposited on a surface of the object 102. Thereafter, the deposited silicon hydroxide is converted into silicon oxide by a poly-condensation reaction due to heat, thereby forming a thin layer comprising the silicon oxide on the object 102 (step S200).

The object 102 on which the silicon oxide layer is formed may be unloaded from the supporting plate 104 (step S300).

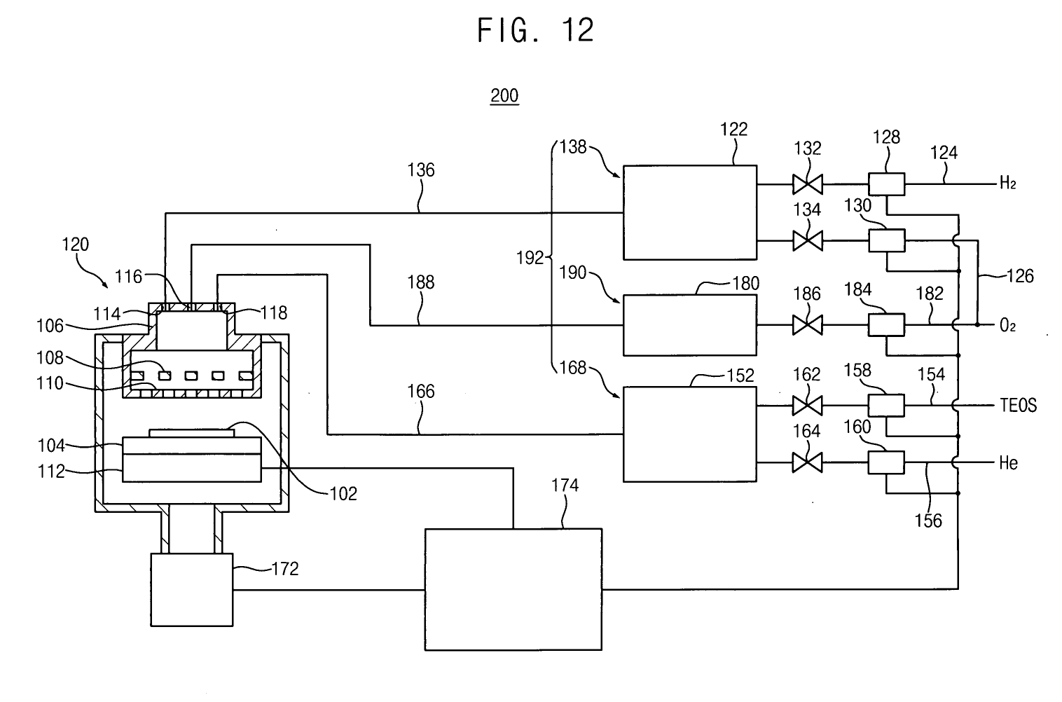

FIG. 12 is a structural view schematically illustrating an apparatus for forming a thin layer for a semiconductor device according to some embodiments of the present embodiment. The apparatus has a similar structure as that described above except that a remote plasma system replaces the ozone generator 140 of the second gas supplier 150 in which the oxygen radical (O*) is generated. Accordingly, the remote plasma system is further described and the other members or units of the apparatus is described to a lesser extent. For this reason, the same reference numbers will be used to refer to the same or like parts as those used above.

Referring to FIG. 12, an apparatus 200 for forming a thin layer for a semiconductor device according to some embodiments of the present invention includes a processing chamber 120, a gas supplier 192, a pressure regulator 172 and a central controller 174.

The processing chamber 120, the pressure regulator 172 and the central controller 174 are the same as previously described, thus any further detailed description is omitted and the gas supplier 192 is described in further detail hereinafter. The gas supplier 192 is connected to the manifold 106 of the processing chamber 120, and supplies processing gases into the processing chamber 120. In some embodiments, the gas supplier 192 includes first, second and third gas suppliers 138, 190 and 168.

The first and third gas suppliers 138 and 168 are the same as previously described, thus any further detailed description is also omitted and the second gas supplier 190 is described in further detail hereinafter. The second gas supplier 190 generates the oxygen gas including the oxygen radical, and supplies the oxygen gas to the processing chamber 120 through an ozone pipe line 188. In some embodiments, the second gas supplier 190 includes a remote plasma system 180 for generating the oxygen radical, a third mass flow controller 184 and a third valve 186.

The remote plasma system 180 is simultaneously connected to a second oxygen pipe line 182, and the oxygen gas is provided into the remote plasma system 180 through the second oxygen pipe line 182. The oxygen gases are activated in the remote plasma system 180 and a portion of the oxygen gas is converted into an ozone gas, thereby forming a mixture of the oxygen gas and the ozone gas.

The third mass flow controller 184 is mounted on the second oxygen pipe line 182, thereby controlling a mass flow of the oxygen gas into the remote plasma system 180.

The third valve 186 is installed on the second oxygen pipe line 182 between the remote plasma system 180 and the third mass flow controller 184.

As shown in FIG. 12, the first and second oxygen pipe lines 126 and 182 are diverted from the same oxygen source (not shown), so that the oxygen gas is supplied to the water vapor generator 122 and the remote plasma system 180 from the same oxygen source in the present invention.

Although the volume ratio of the ozone gas with respect to the mixture of the oxygen gas and the ozone gas is in a range of about 5% to about 20% in the ozone generator 140 of the second gas supplier 150, there is no limit on a range of the volume ratio of the ozone gas in the remote plasma system 180 according to some embodiments of the present invention.

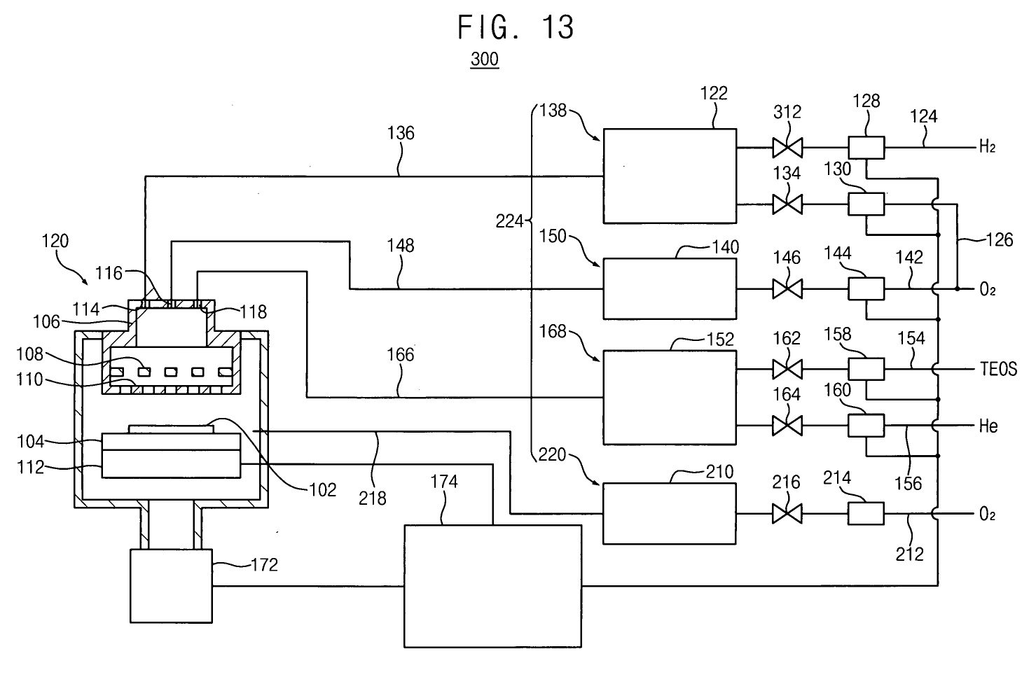

FIG. 13 is a structural view schematically illustrating an apparatus for forming a thin layer for a semiconductor device according to some embodiments of the present invention. The apparatus have a similar structure as those described above except that a fourth gas supplier is present. Accordingly, the fourth gas supplier is described in further detail and the other members or units of the apparatus are described to a lesser extent. For this reason, the same reference numbers will be used to refer to the same or like parts as those used above.

Referring to FIG. 13, an apparatus 300 for forming a thin layer for a semiconductor device according to some embodiments of the present invention includes a processing chamber 120, a gas supplier 224, a pressure regulator 172 and a central controller 174.

The processing chamber 120, the pressure regulator 172 and the central controller 174 are the same as described previously, thus any further detailed description is omitted and the gas supplier 224 is described in further detail hereinafter. In some embodiments, the gas supplier 224 includes first, second, third and fourth gas suppliers 138, 150, 168 and 220. The first, second and third gas suppliers 138, 150 and 168 are connected to the manifold 106 of the processing chamber 120, and supply processing gases into the processing chamber 120, as described previously. The fourth gas supplier 220 is connected to another portion of the processing chamber 120 such as a port (not shown) for a residual gas analysis, and an oxygen gas including an oxygen radical is supplied into the processing chamber 120 by the fourth gas supplier 220.

The first, second and third gas suppliers 138, 150 and 168 are the same as described above, thus any further detailed description is also omitted and the fourth gas supplier 220 is described in further detail hereinafter. The fourth gas supplier 220 generates the oxygen gas including the oxygen radical, and supplies the oxygen gas to the processing chamber 120 through a supplementary pipe line 218. In some embodiments, the fourth gas supplier 220 includes a remote plasma system 210 for generating the oxygen radical, a sixth mass flow controller 214 and a sixth valve 216.

The remote plasma system 210 is simultaneously connected to a supplementary oxygen pipe line 212, and the oxygen gas is provided into the remote plasma system 210 through the supplementary oxygen pipe line 212. The oxygen gases are activated in the remote plasma system 210 and a portion of the oxygen gas is converted into an ozone gas, thereby forming a mixture of the oxygen gas and the ozone gas.

The sixth mass flow controller 214 is mounted on the supplementary oxygen pipe line 212, thereby controlling a mass flow of the oxygen gas flowing into the remote plasma system 210.

The sixth valve 216 is installed on the supplementary oxygen pipe line 212 between the remote plasma system 210 and the sixth mass flow controller 214.

According to some embodiments, the oxygen gas including the oxygen radical is supplied into the processing chamber 120 from one of the water vapor generators 122 and the remote plasma system 210 or from both of the water vapor generators 122 and the remote plasma system 210.

According to the ozone generator 140 of the second gas supplier 150, the volume ratio of the ozone gas with respect to the mixture of the oxygen gas and the ozone gas is limited in a range of about 5% to about 20%, and a maximum flow rate of the ozone gas is at most about 17 liters/min. However, according to the remote plasma generator 210 according to some embodiments, the oxygen radical is supplied to the processing chamber 120 in addition to the oxygen radical supplied from the ozone generator 140.

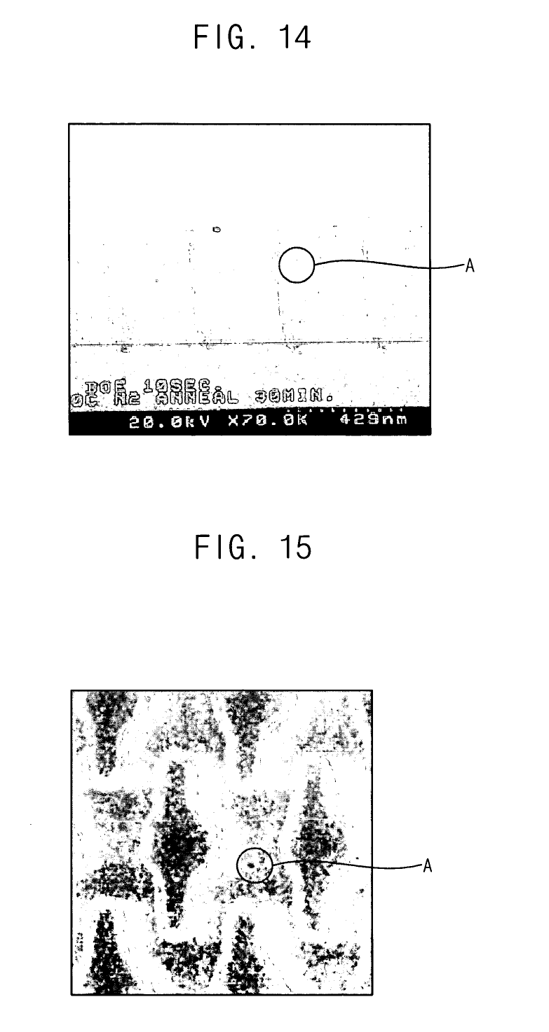

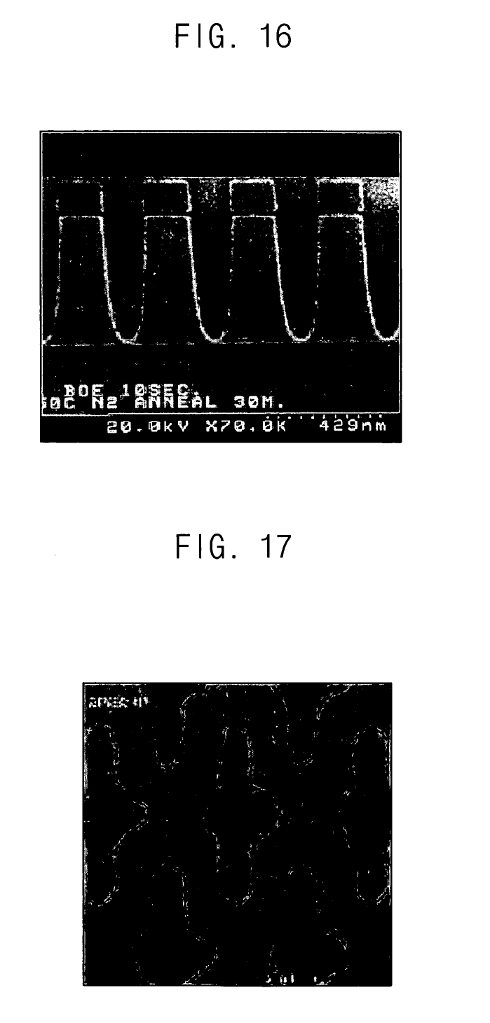

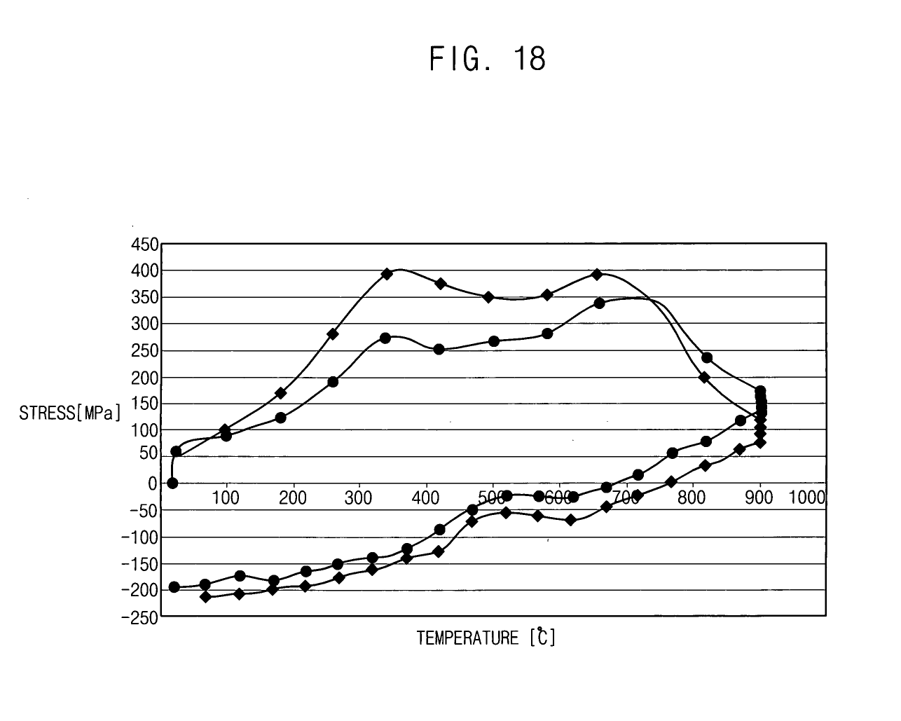

FIG. 14 is a vertical picture of a conventional insulation layer filling a recessed portion of a substrate vertically taken by a scanning electron microscope (SEM), and FIG. 15 is a horizontal picture of a conventional insulation layer filling a recessed portion of a substrate horizontally taken by a SEM. FIG. 16 is a vertical picture of an insulation layer filling a recessed portion of a substrate according to some embodiments of the present invention taken vertically by a SEM, and FIG. 17 is a horizontal picture of a conventional insulation layer filling a recessed portion of a substrate according to some embodiments of the present invention horizontally taken by a SEM.

A first recessed portion was formed on a first substrate and a second recessed portion was formed on a second substrate in the same process as described above concerning methods of forming a thin layer. Then, a thin layer was formed on each of the substrates in different processes.

A silicon oxide layer was formed on the first substrate by a conventional SACVD process at a temperature of about 540° C. and a pressure of about 600 Torr.

An insulation layer was formed on the second substrate by the same process described above concerning methods of forming a thin layer. Particularly, the water vapor, the oxygen gas including the oxygen radical and the TEOS were supplied to the processing chamber at a flow rate of about 4000 sccm, of about 7500 sccm and of about 100 sccm, respectively, at a temperature of about 540° C. and a pressure of about 600 Torr.

The silicon oxide layer on the first substrate and the insulation layer on the second substrate were inspected by a SEM in a view of a gap-fill characteristic thereof. While FIGS. 14 and 15 show that the silicon oxide layer on the first substrate includes a seam defect A, no seam defect is found in the insulation layer on the second substrate as shown in FIGS. 16 and 17.

Accordingly, the above estimation on a gap-fill characteristic of a thin layer shows that the gap-fill characteristic of a thin layer is sufficiently improved by the methods of the present invention.

A thin layer was formed on each of first and second blank substrates in different processes. A silicon oxide (SiO2) layer was formed on the first blank substrate by a conventional SACVD process at a temperature of about 540° C. and a pressure of about 600 Torr.

An insulation layer was formed on the second blank substrate by the same process as described above concerning methods of forming a thin layer. Particularly, the water vapor, the oxygen gas including the oxygen radical (O*) and the TEOS were supplied to the processing chamber at a flow rate of about 4000 sccm, of about 7500 sccm and of about 100 sccm, respectively, at a temperature of about 540° C. and a pressure of about 600 Torr.

A thickness of each layer on the first and second blank substrates was measured and divided by a deposition time, thereby obtaining a deposition rate of each layer. The thickness of the layer was measured in units of angstrom (A), and the deposition time was measured in units of minute. The deposition rate of each layer is shown in Table 1.

TABLE 1

| | Silicon oxide layer | Insulation layer |
|---|---|---|
| Deposition rate | 120 Å/min | 170 Å/min |

Table 1 shows that the silicon oxide layer is coated on the first substrate at a rate of about 120 Å/min in a conventional process and the insulation layer is coated on the second substrate at a rate of about 170 Å/min in the same process as described previously.

Accordingly, the above estimation on a deposition rate shows that a thin layer is coated on an object in shorter time utilizing methods according to the present invention, thereby sufficiently improving a productivity of a semiconductor device.

A thin layer was formed on each of first and second blank substrates in different processes. A silicon oxide layer was formed on the first blank substrate to a thickness of about 2000 Å by a conventional SACVD process at a temperature of about 540° C. and a pressure of about 600 Torr.

An insulation layer was formed on the second blank substrate by the same process as described above concerning methods of forming a thin layer. Particularly, the water vapor, the oxygen gas including the oxygen radical and the TEOS were supplied to the processing chamber at a flow rate of about 4000 sccm, of about 7500 sccm and of about 100 sccm, respectively, at a temperature of about 540° C. and a pressure of about 600 Torr.

A thermal stress in each layer was measured with various temperatures, as shown in FIG. 18. In particular, FIG. 18 is a graph illustrating a stress hysteresis of each of the silicon oxide layer on the first substrate and the insulation layer on the second substrate. In FIG. 18, a horizontal line indicates a temperature of the substrate and a vertical line indicates a measured thermal stress of each layer on the first and second substrates. A mark ‘♦’ indicates a thermal stress of the silicon oxide layer in accordance with a temperature of the first substrate in a conventional SACVD process, and a mark ‘•’ indicates a thermal stress of the insulation layer in accordance with a temperature of the second substrate in the same process as in Embodiment 1.

As shown in FIG. 18, a stress hysteresis curve on the insulation layer formed using methods of the present invention is almost positioned inside of a stress hysteresis curve on the silicon oxide layer formed by a conventional process, so that the thermal stress is released more in the insulation layer according to some embodiments of the present invention than in the silicon oxide layer formed by the conventional process.

As a result, layer shrinkage during a subsequent heat treatment is more sufficiently prevented in the insulation layer according to some embodiments of the present invention than in the silicon oxide layer formed by the conventional process.

According to some embodiments of the present invention, a flow characteristic of a thin layer is sufficiently improved, so that a seam defect is sufficiently prevented in the thin layer when a recessed portion on an object is filled with the thin layer.

Although the exemplary embodiments of the present invention have been described, it is understood that the present invention should not be limited to these exemplary embodiments but various changes and modifications can be made by one of ordinary skill in the art within the spirit and scope of the present invention as hereinafter claimed.

What is claimed is:

1. A method of forming a thin layer for a semiconductor device, comprising:
forming a recessed portion on an object; and
forming an insulation layer on the object by reacting a water vapor, an oxygen gas comprising an oxygen radical and an organic silicon source gas with each other, so that the recessed portion is filled with the insulation layer.

2. The method of claim 1, wherein the organic silicon source gas comprises a tetra ethoxy silane (Si(OC₂H₅)₄) gas, a tetra methoxy silane (Si(OCH₃)₄) gas, a tetra isopropoxy silane (Si(i-OC₃H₇)₄) gas, a tetra tertiary butoxy silane (Si(t-OC₄H₉)₄) gas or a combination thereof.

3. The method of claim 1, wherein the water vapor is produced by chemically reacting a hydrogen gas with an oxygen gas.

4. The method of claim 1, wherein the water vapor is supplied at a flow rate ratio of about 40 to about 75 with respect to the organic silicon gas, and the oxygen gas comprising the oxygen radical is supplied at a flow rate ratio of about 75 to about 170 with respect to the organic silicon gas during formation of the insulation layer.

5. The method of claim 1, wherein the insulation layer is formed at a pressure lower than an atmospheric pressure.

6. The method of claim 1, wherein the insulation layer is formed at a temperature in a range of about 25° C. to about 550° C.

7. The method of claim 1, wherein the object comprises a semiconductor substrate.

8. The method of claim 7, wherein the recessed portion comprises a trench on the semiconductor substrate.

9. The method of claim 1, wherein the object comprises one of a thin layer and a conductive structure on a semiconductor substrate, and the recessed portion comprises one of a via-hole or a contact hole penetrating the thin layer and a gap between the conductive structures.

10. A method of forming a thin layer for a semiconductor device, comprising:
forming a recessed portion on an object;
forming a first insulation layer on the object and inner surfaces of the recessed portion by reacting an organic silicon source gas with an ozone gas, so that a size of the recessed portion is reduced, thereby forming a reduced recess; and
forming a second insulation layer on the first insulation layer by reacting a water vapor, an oxygen gas comprising an oxygen radical and an organic silicon source gas with each other, so that the reduced recess is filled with the second insulation layer.

11. The method of claim 10, wherein the organic silicon source gas comprises a tetra ethoxy silane (Si(OC₂H₅)₄) gas, a tetra methoxy silane (Si(OCH₃)₄) gas, a tetra isopropoxy silane (Si(i-OC₃H₇)₄) gas, a tetra tertiary butoxy silane (Si(t-OC₄H₉)₄) gas or a combination thereof.

12. The method of claim 10, wherein the water vapor is produced by chemically reacting a hydrogen gas with an oxygen gas.

13. The method of claim 10, wherein the water vapor is supplied at a flow rate ratio of about 40 to about 75 with respect to the organic silicon gas, and the oxygen gas comprising the oxygen radical is supplied at a flow rate ratio of about 75 to about 170 with respect to the organic silicon gas during formation of the insulation layer.

14. The method of claim 10, wherein the insulation layer is formed at a pressure lower than an atmospheric pressure.

15. The method of claim 10, wherein the insulation layer is formed at a temperature in a range of about 25° C. to about 550° C.

16. The method of claim 10, wherein the object comprises a semiconductor substrate.

17. The method of claim 16, wherein the recessed portion comprises a trench on a semiconductor substrate.

18. The method of claim 8, wherein the object comprises one of a thin layer and a conductive structure on a semiconductor substrate, and the recessed portion comprises one of a via-hole or a contact hole penetrating the thin layer and a gap between the conductive structures.

19. An apparatus for forming a thin layer for a semiconductor device, comprising:
a processing chamber into which an object comprising a recessed portion is loaded, an insulation layer being formed on the object and the recessed portion being filled with the insulation layer in the processing chamber;
a first gas supplier for supplying a water vapor into the processing chamber;
a second gas supplier for supplying an oxygen gas comprising an oxygen radical into the processing chamber; and
a third gas supplier for supplying an organic silicon source gas into the processing chamber.

20. The apparatus of claim 19, wherein the first gas supplier comprises:
a water vapor generator for generating the water vapor by chemically reacting an oxygen gas with a hydrogen gas;
at least one supplying line for supplying the hydrogen gas and the oxygen gas into the water vapor generator;
at least one exhausting line connected between the water vapor generator and the processing chamber, the water vapor being supplied from the water vapor generator into the processing chamber through the exhausting line; and
a flow rate controller positioned on the supplying line, thereby controlling a flow rate of the hydrogen gas and the oxygen gas.

21. The apparatus of claim 19, further comprising a central controller for transferring a control signal to each of the first, second and third gas suppliers, so that the water vapor, the oxygen gas comprising the oxygen radical and the organic silicon source gas are supplied into the processing chamber at a predetermined flow rate ratio.

22. The apparatus of claim 19, further comprising pressure regulator and/or heater.

23. The apparatus of claim 19, further comprising a pressure regulator connected to the processing chamber, the pressure regulator maintaining an internal pressure of the processing chamber to be lower than about 760 Torr.

24. The apparatus of claim 19, further comprising a heater for heating the object to a temperature of about 25° C. to about 550° C.

25. The apparatus of claim 19, wherein the second gas supplier comprises an ozone generator for generating the ozone radical.

26. The apparatus of claim 24, wherein the ozone generator comprises a remote plasma system.

27. The apparatus of claim 19, further comprising a fourth gas supplier for additionally supplying the oxygen gas comprising the oxygen radical into the processing chamber.

28. The method of claim 26, wherein the fourth gas supplier comprises a remote plasma system for generating the ozone radical.
